(19) United States
(12) Patent Application Publication
(10) Pub. No.: US 2009/0283760 A1
(43) Pub. Date: Nov. 19, 2009

(54) Semiconductor device having principal surface of polar plane and side surface at specific angle to nonpolar plane and manufacturing method of the same

(75) Inventor: Tetsuo Fujii, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyot-fu (JP)

(21) Appl. No.: 12/222,386

(22) Filed: Aug. 7, 2008

(30) Foreign Application Priority Data
Aug. 8, 2007 (JP) 2007-206939

(51) Int. Cl. H01L 29/22; H01L 21/304; H01L 21/18

(52) U.S. Cl. 257/43; 438/462; 438/455; 438/104; 257/E29.094; 257/E21.238; 257/E21.088

(57) ABSTRACT

A semiconductor device includes a substrate which is composed of a zinc oxide semiconductor having a hexagonal crystal structure and includes a first principal surface which is a polar plane; and four side surfaces which are adjacent to the first principal surface, the side surfaces being orthogonal to the principal surface and are at angles of 40 to 50 degrees to a base nonpolar plane orthogonal to the first principal surface; and a semiconductor layer provided on the first principal surface.

### CROSS REFERENCE TO RELATED APPLICATIONS AND INCORPORATION BY REFERENCE

This application is based upon and claims the benefit of priority from prior Japanese Patent Application P2007-206939 filed on August 8, 2007; the entire contents of which are incorporated by reference herein.

### BACKGROUND OF THE INVENTION

1. Field of the Invention

The present invention relates to a semiconductor device including a zinc oxide substrate having a polar plane as a principal surface and a method of manufacturing of the same.

2. Description of the Related Art

A zinc oxide (ZnO) crystal is a direct transition semiconductor having a band gap of about 3.4 eV. In the ZnO crystal, a binding energy of an exciton, which is a bound state of a hole and an electron in a solid, is as large as 60 meV. The exciton in the ZnO crystal therefore exists stably even at room temperature. Accordingly, the ZnO crystal is cheep, has low environmental load, and is expected to be applied to light emitting devices in a blue to ultraviolet range. In addition to the light emitting devices, ZnO semiconductors are used in various applications and are expected to be applied to, for example, light receiving devices, piezoelectric devices, transparent electrodes, and the like.

Generally, to divide a substrate with semiconductor devices formed thereon into chips, division by dicing or cleavage by a scriber is used. In the division by dicing, the rear surface or front surface of the substrate is ground by a blade rotating at high speed once or a plurality of times to divide the substrate. In the cleavage by a scriber, V-shaped trenches are formed in the substrate with a pen provided with diamond at the tip or the like, and the substrate is divided by cleavage along the trenches.

In the case of dividing a substrate composed of a ZnO semiconductor (hereinafter, referred to as a “ZnO” substrate) into chips by cleavage, it is necessary to consider crystal faces of the substrate. The ZnO substrate has a hexagonal crystal structure as well as a gallium nitride (GaN) substrate and the like. Accordingly, easiest cleavage planes in the ZnO substrate whose principal surface is a c-plane (polar plane) are (1-100) planes called as m-planes (nonpolar planes). The m-planes correspond to side faces of a hexagonal prism parallel to the c-axis [0001]. In other words, the ZnO or GaN substrate whose principal surface is a c-plane includes the easiest cleavage planes at every 60 degrees.

One of methods of dividing the GaN substrate whose principal surface is the c-plane into chips is dividing the substrate along the easiest cleavage planes. Since the easiest cleavage planes of the GaN substrate are not orthogonal to each other, the principal surfaces of chips have a shape of an equilateral triangle, a hexagon, a parallelogram, or a trapezoid. However, in view of current package designs, substrate effective area, and the like, it is desirable that the shape of the principal surfaces of chips is a rectangle such as a square or an oblong.

However, when the substrate is cleaved along planes other than the easiest cleavage planes in order to obtain chips having rectangular principal surfaces, cracks occur around the cutting places in the surfaces of the chips, some of desired cutting places are not cut, or the substrate is cut at a place other than the desired cutting places, thus reducing the yield of semiconductor devices.

On the other hand, cutting a substrate into chips by dicing requires dicing regions with a width equal to edge thickness of the blade in the surface of the substrate and reduces an area where semiconductor devices can be arranged. Furthermore, cutting a substrate by dicing often requires a step of eliminating damages caused in the cutting surfaces by wet etching. The ZnO semiconductor is more anisotropic in wet etching than other semiconductor materials and has low chemical resistance. Accordingly, if the chip making step, which is performed at an end of the manufacturing process of the semiconductor devices, includes wet etching, the yield thereof could be reduced.

### SUMMARY OF THE INVENTION

An aspect of the present invention is a semiconductor device including a substrate which is composed of a zinc oxide semiconductor having a hexagonal crystal structure and includes a first principal surface which is a polar plane; and four side surfaces which are adjacent to the first principal surface, the side surfaces being orthogonal to the principal surface and are at angles of 40 to 50 degrees to a base nonpolar plane orthogonal to the first principal surface; and a semiconductor layer provided on the first principal surface.

Another aspect of the present invention is a method of manufacturing a semiconductor device in which a substrate is divided into a plurality of chips, the substrate including a first polar principal surface and a second principal surface opposite to the first principal surface. The method includes setting a base nonpolar plane; determining positions of cutting planes at angles of 40 to 50 degrees to the base nonpolar plane; and cutting the substrate along the cutting planes into the plurality of chips.

Still another aspect of the present invention is a semiconductor device including a substrate which is composed of a zinc oxide semiconductor having a hexagonal crystal structure and includes a first principal surface which is a polar plane; and four side surfaces which are adjacent to the first principal surface and orthogonal to the principal surface; and a semiconductor layer provided on the first principal surface, wherein the four side surfaces are substantially different from nonpolar a- or m-planes and planes equivalent to the a- or m-planes.

### BRIEF DESCRIPTION OF THE DRAWINGS

FIG. 1 is a schematic view showing a structure example of a semiconductor device according to an embodiment of the present invention.

FIG. 2 is a top plan view of the semiconductor device shown in FIG. 1.

FIG. 3 is a bottom plan view of the semiconductor device shown in FIG. 1.

FIG. 4 is a cross-sectional view in a direction along a side surface of the semiconductor device shown in FIG. 1.

FIG. 5 is a schematic view for explaining a crystal structure of a hexagonal crystal.

FIG. 6 is a schematic view showing an upper surface of a substrate of the semiconductor device according to the embodiment of the present invention together with a hexagonal crystal structure and cutting planes.

FIG. 7 is a schematic view showing an example of a cutting plane of the semiconductor device together with the hexagonal crystal structure.

FIG. 8 is a photograph showing an example of a substrate cut along the cutting plane shown in FIG. 6.

FIG. 9 is a photograph showing an example of a substrate cut along the cutting plane shown in FIG. 7.

FIG. 10 is a schematic view showing an example of the substrate before dividing into chips for the semiconductor device according to the embodiment of the present invention.

FIG. 11 is a cross-sectional process view for explaining an example of the method of manufacturing a semiconductor device according to the embodiment of the present invention.

FIG. 12 is a cross-sectional process view for explaining the example of the method of manufacturing a semiconductor device according to the embodiment of the present invention.

FIG. 13 is a cross-sectional process view for explaining the example of the method of manufacturing a semiconductor device according to the embodiment of the present invention.

FIG. 14 is an optical micrograph showing an example of the cutting plane of the semiconductor device according to the embodiment of the present invention.

FIG. 15 is an optical micrograph showing an example of the cutting plane of the semiconductor device according to the embodiment of the present invention.

FIG. 16 is an electron micrograph of an enlarged part of the micrograph shown in FIG. 15.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

Generally and as it is conventional in the representation of semiconductor devices, it will be appreciated that the various drawings are not drawn to scale from one figure to another nor inside a given figure.

In the following descriptions, numerous specific details are set forth such as specific signal values, etc., to provide a thorough understanding of the present invention. However, it will be obvious to those skilled in the art that the present invention may be practiced without such specific details.

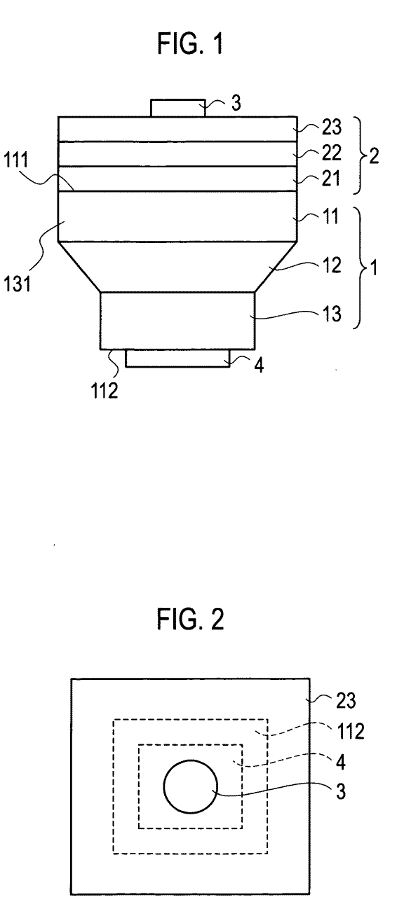

As shown in FIG. 1, a semiconductor device according to an embodiment of the present invention includes: a substrate 1; and a semiconductor layer 2 provided on a first principal surface 111. The substrate 1 is composed of a zinc oxide semiconductor having a hexagonal crystal structure. The first principal surface 111 is a polar plane (c-plane), and side surfaces orthogonal to the first principal surface 111 are planes different from planes equivalent to a- or m-planes and close thereto. In other words, the side surfaces are planes substantially different from planes equivalent to the a- or m-planes. More specifically, the substrate 1 is composed of a zinc oxide semiconductor having a hexagonal crystal structure and includes a structure having the polar first principal surface 111 and four side surfaces adjacent to the first principal surface 111. The four side surfaces are at angles of 40 to 50 degrees to a base nonpolar plane that is orthogonal to the first principal surface 111, and the four side surfaces are orthogonal to the first principal surface 111. The zinc oxide semiconductor (ZnO) is a ZnO-based mixed crystal material. Specifically, the ZnO semiconductor includes a ZnO semiconductor with a part of zinc (Zn) being substituted with a IIA or IIB group, a ZnO semiconductor with a part of oxygen (O) being substituted with a VIB group, and a combination thereof. Examples of the ZnO semiconductor include a mixed crystal MgₓZn₁₋ₓO (0<=x<1) of ZnO and magnesium (Mg).

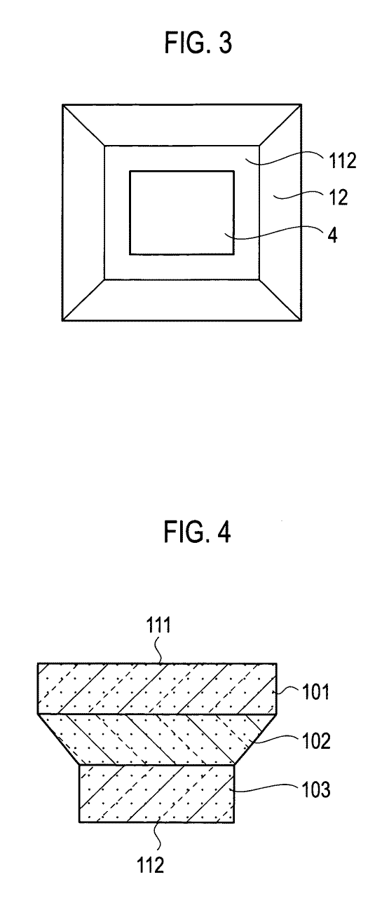

FIGS. 2 and 3 show top and bottom plan views of the semiconductor device shown in FIG. 1, respectively. In the following description, the first principal surface 111 in contact with the semiconductor layer 2 is referred to as a “front surface” of the substrate 1, and a second principal surface 112 opposite to the first principal surface 111 is referred to as a “rear surface” of the substrate 1. FIG. 1 is a side view of the semiconductor device from a side surface 131 of the substrate 1. Side views of the semiconductor device from the other side surfaces are the same as FIG. 1. As shown in FIGS. 1 to 3, the front surface 111 and the rear surface 112 are rectangular, and the area of the rear surface 112 is smaller than the area of the front surface 111.

As shown in FIG. 1, the substrate 1 includes: a first cuboid region 11 which is a cuboid including the surface 111 as a face; a second cuboid region 13 which is a cuboid including the rear surface 112 as a face; and a truncated rectangular pyramid region 12 provided between the first cuboid region 11 and the second cuboid region 13. The truncated rectangular pyramid region 12 having a structure obtained by cutting a rectangular pyramid along a plane parallel to the base. In other words, the truncated rectangular pyramid region 12 has a structure obtained by cutting off a rectangular pyramid whose base is a face of the first cuboid region 11 opposite to the front surface 111 along a plane parallel to the base. The second cuboid region 13 is a cuboid whose face opposite to the rear surface 112 is a truncated surface of the truncated rectangular pyramid region 12. As shown in FIG. 4, the cross section along each side surface of the substrate 1 is therefore composed of a first rectangular region 101 orthogonal and adjacent to the front surface 111; a second rectangular region 103 orthogonal and adjacent to the rear surface 112; and a trapezoidal region 102 connecting the first rectangular region 101 and the second rectangular region 103.

As described later, side faces of the first cuboid region 11 orthogonal to the front surface 111 are cleavage planes cut by cleavage, and the side faces of the second cuboid region 13 and truncated rectangular pyramid region 12 are cutting planes cut by a dicing blade.

The semiconductor layer 2 is composed of a ZnO semiconductor stack having a structure including: an n-type MgZnO layer 21 doped with gallium (Ga); an undoped MgZnO layer 22; a p-type MgZnO layer 23 doped with nitrogen (N) which are stacked in this order. In this case, the semiconductor layer 2 is a light emitting diode (LED) including an n-type first semiconductor layer, an active layer, and a p-type semiconductor layer stacked. The semiconductor layer 2 is formed on the substrate 1 by crystal growth by means of for example, molecular beam epitaxy (MBE) or the like.

As shown in FIGS. 1 to 3, the semiconductor device according to the embodiment of the present invention further includes: an upper electrode 3 ohmically connected to the semiconductor layer 2; and a lower electrode 4 ohmically connected to the rear surface 112 of the substrate 1. The upper electrode 3 supplies holes to the p-type MgZnO layer 23, and the lower electrode 4 supplies electrons to the n-type MgZnO layer 21 through the substrate 1. The holes and electrons supplied to the semiconductor layer 2 are recombined to produce light. The upper electrode 3 can be a layered structure of nickels (Ni) and gold (Au), for example. The lower electrode 4 can be a layered structure of titanium (Ti) and gold (Au), for example.

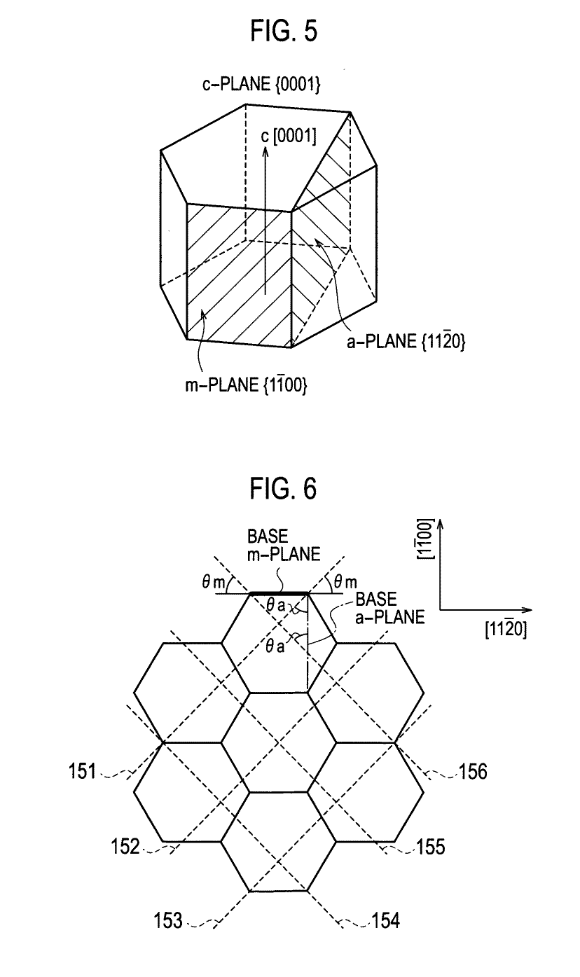

A description is given of a crystal structure of ZnO with reference to FIG. 5. FIG. 5 is a schematic view showing a unit cell of the crystal structure of ZnO. The crystal structure is approximated to a hexagonal system.

The c-axis [0001] of the hexagonal system extends in an axial direction of a hexagonal cylinder, and a face whose normal line is the c-axis (top face) is a c-plane (0001). The c-plane is different in property between on +c and −c sides and is called a polar plane. The crystal having a hexagonal crystal structure has a polarization direction along the c-axis.

In the hexagonal system, each of six side faces of the hexagonal cylinder is an m-plane (1-100), and each plane including a pair of ridges not adjacent to each other is an a-plane (11-20). These planes are crystal faces perpendicular to the c-plane and orthogonal to the polarization direction. Accordingly, the above planes are not polarized planes, that is, nonpolar planes.

FIG. 6 shows a part of the upper surface of the substrate on which a plurality of the semiconductor devices shown in FIG. 1 are formed together with a hexagonal crystal structure. FIG. 6 is a view of the hexagonal crystal structure in the normal direction of the c-plane which is a top face of the prism, in which each unit cell of the hexagonal crystal structure is indicated by solid lines. In FIG. 6, the m-planes of each unit cell are indicated by solid lines. In FIG. 6, a base nonpolar m-plane (hereinafter, referred to as a “base m-plane”) as a base of cutting planes for dividing the substrate into a plurality of chips is indicated by heavy solid lines. A description is given of the embodiment of the present invention with the base nonpolar plane being set to the base m-plane. In the substrate where the semiconductor devices are formed, the base of the plane orientation such as an orientation flat for example is provided in advance, and the base m-plane can be therefore set using such a base of the plane orientation.

Furthermore, cutting lines 151 to 156 showing cutting planes along which the substrate is divided into a plurality of chips are indicated by dashed lines. The cutting planes are surfaces obtained by cutting the substrate 1 along the cutting lines 151 to 156. A first cutting direction that the cutting lines 151 to 153 extend is orthogonal to a second cutting direction that the cutting lines 154 to 156 extend. In other words, the principal surfaces of the chips obtained by dividing the substrate along the cutting lines 151 to 156 are rectangular. The chips whose principal surfaces are rectangular are referred to as rectangular chips below. FIG. 6 shows only the six cutting lines 151 to 156 orthogonal to each other for convenience, but it is obvious that the number of cutting lines is determined based on the area of the substrate 1 not yet divided and the area of each divided rectangular chip.

The cutting lines 151 to 156 are set at angles θm of 40 to 50 degrees to the base m-plane. Accordingly, angles between the cutting lines 151 to 156 and an a-plane orthogonal to the base m-plane, which is indicated by a dashed-dotted line, (hereinafter, referred to as a “base a-plane”) are 40 to 50 degrees.

In the ZnO substrate whose principal surface is the c-plane, directions that the m-axes as plane normals of the m-planes extend and directions that the a-axes as plane normals of the a-planes extend are at every 30 degrees. Accordingly, when a side face of each rectangular chip is set perpendicular to an m-axis for dividing the substrate, the side face adjacent to the side face perpendicular to the m-axis is perpendicular to an a-axis. The substrate can be divided by cleavage perpendicular to the a-axis, or parallel to the a-plane. However, it is necessary to polish the substrate so that the thickness of the substrate is reduced to about 50 to 100 μm and then form accurate V-shaped trenches with a scriber for cleavage. Since the easiest cleavage planes of the ZnO substrate are m-planes, the substrate can be broken along an m-plane at 30 degrees to an a-plane along which the substrate is intended to be cleaved when the accuracy of the direction that the trench extends perpendicularly to the a-axis, accuracy of the V-shape of the trench, conditions of breaking in which stress is applied to the substrate after the trench is formed, or the like is not proper. Accordingly, cleavage at a-planes reduces the yield. Moreover, the substrate is polished and thinned, and such a substrate is difficult to handle.

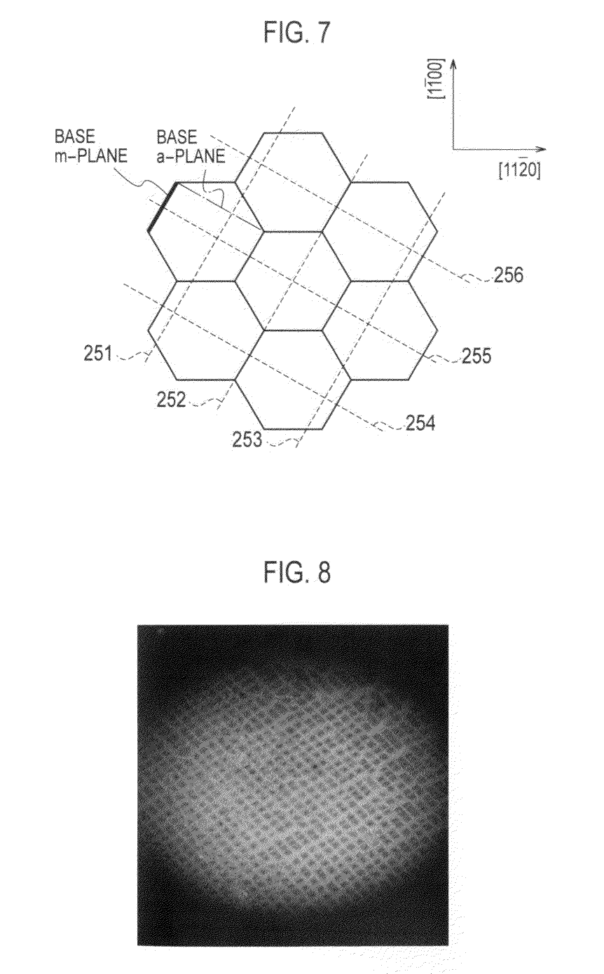

For example, as shown in FIG. 7, in the case of forming trenches for cleavage along the cutting lines 251 to 256 set parallel to m- or a-axes, the trenches along the cutting lines 251 to 253 perpendicular to the m-axes are parallel to m-planes and therefore facilitate the cleavage. However, the substrate is not cleaved along the trenches along the cutting lines 151 to 156 perpendicular to the a-axes even after breaking, and the adjacent two chips remain uncut into so-called twin chips.

On the other hand, as shown in FIG. 6, in the case of setting the angles θm between the cutting lines 151 to 156 and the base m-plane and the angles θa between the cutting lines 151 to 156 and the base a-plane to 40 to 50 degrees, the directions that the m-axes of the hexagonal system extend and the directions that the a-axes extend are at every 30 degrees. Accordingly, the directions where the cutting lines 151 to 156 extend are not parallel to either the m- or a-plane. In other words, each of the cutting lines 151 to 156 extends in a direction between any m- and a-planes of the hexagonal system. Accordingly, the twin chips are not produced, thus preventing the reduction in yield of semiconductor devices can be reduced.

If the angles θm and θa are shifted by 15 degrees from 45 degrees, the cutting lines 151 to 156 are parallel to any m- or a-plane. The angles θm and θa are therefore set to 40 to 50 degrees and preferably 45 degrees. Normally, the substrate is provided with a base of plane orientation such as an orientation flat, and it is easy to set the cutting lines 151 to 156 using the base of plane orientation so that the angles θm are 45±5 degrees.

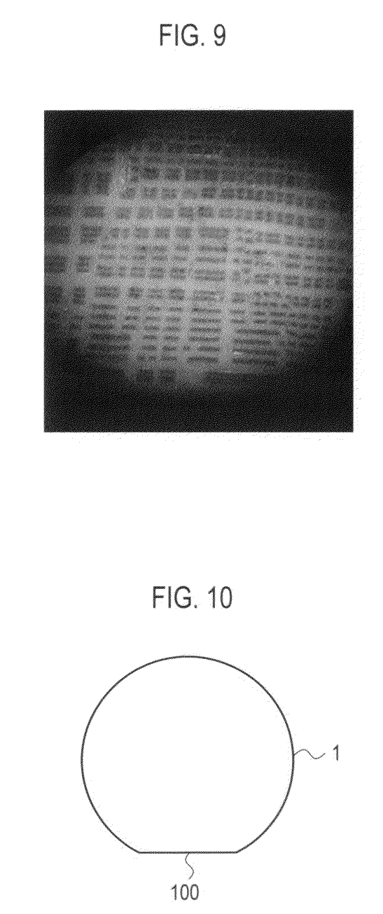

FIG. 8 shows an example of the substrate cleaved along the cutting lines 151 to 156 shown in FIG. 6, and FIG. 9 shows an example of the substrate cleaved along the cutting lines 251 to 256 shown in FIG. 7. FIGS. 8 and 9 are top plan views of the substrate 1 after cleavage. The example shown in FIG. 8 include few twins of connected chips while the example shown in FIG. 9 include many twin chips.

As described above, according to the semiconductor device of the embodiment of the present invention, it is possible to obtain semiconductor devices divided as rectangular chips while preventing the reduction in yield.

A description is given below of a method of manufacturing a semiconductor device according to the embodiment of the present invention. The method of manufacturing a semiconductor device described below is just an example, and it is obvious that, in addition to this method, various manufacturing methods including modifications thereof can be implemented.

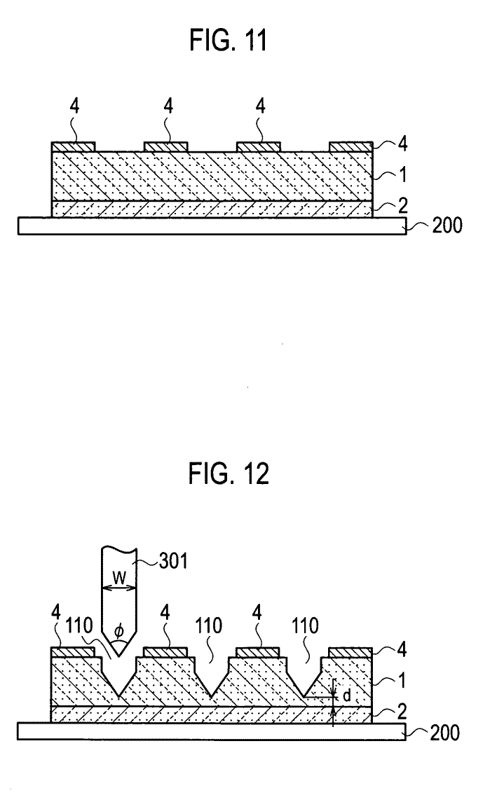

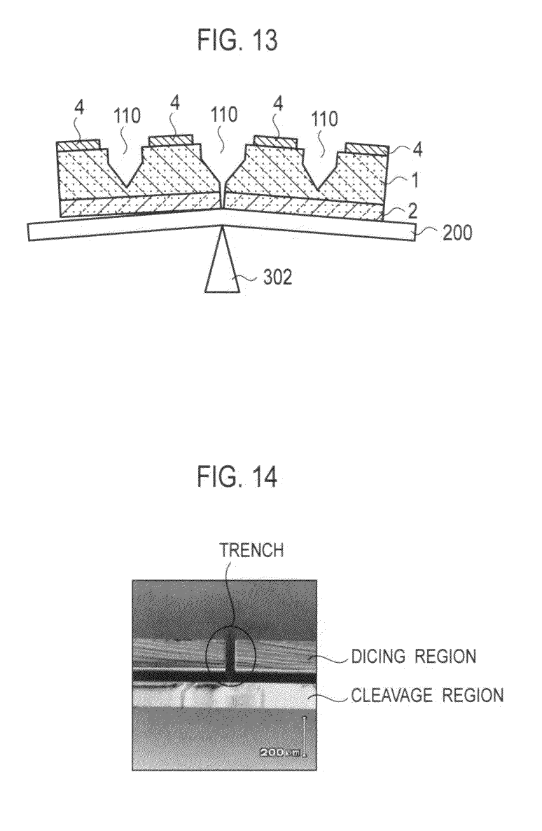

(a) The substrate 1 which is composed of a ZnO semiconductor and whose principal surface is c-plane is prepared. In the substrate 1, as shown in FIG. 10, an orientation flat 100 is provided in advance as a base of the plane orientation. The orientation flat 100 is parallel to an m-plane. The thickness of the substrate 1 is about 350 μm, for example. The substrate 1 is subjected to surface processing and then conveyed into an MVE machine. In the surface processing, for example, the substrate is etched with hydrochloride and then washed with pure water, followed by drying with dry nitrogen.
(b) The semiconductor layer 2 is crystal-grown on the surface 111 of the substrate 1 by MBE. Specifically, the n-type MgZnO layer 21 doped with Ga, the undoped MgZnO layer 22, and the p-type MgZnO layer 23 doped with nitrogen are stacked in this order. The n-type MgZnO layer 21 can be, for example, a Mg_{0.1}Zn_{0.9}O film with a Ga doping concentration of 5×10¹⁸ cm⁻³. The undoped MgZnO layer 22 can be, for example, Mg_{0.02}Zn_{0.98}O film. The p-type MgZnO layer 23 can be, for example, Mg_{0.1}Zn_{0.9}O film with an nitrogen doping concentration of 5×10¹⁸ cm⁻³.
(c) On the semiconductor layer 2, the upper electrode 3 is formed using photolithography or the like. Specifically, the photoresist film is applied to the entire surface of the semiconductor layer 2, and then part of the photoresist film where the upper electrode 3 is formed is removed by photolithography to expose a part of the semiconductor layer 2. Subsequently, on the photoresist film and the exposed part of the semiconductor layer 2, the first conductor layer which serves as the upper electrode 3 is formed by sputtering or the like. The first conductor layer can be for example a layered stack of Ni and Au or the like. The upper electrode 3 is then formed by the lift off method using a photoresist film.
(d) The rear surface 112 of the substrate 1 is polished so that the substrate 1 s about 100 μm thick by a lapping machine provided with diamond slurry or the like.
(e) Using the orientation flat 100 provided for the substrate 1, the base nonpolar plane (base m-plane) is set. Specifically, an m-plane parallel to the orientation flat 100 is set to the base m-plane, for example.
(f) On the basis of the base m-plane, the positions of the cutting planes are determined so that the cutting planes are at 40 to 50 degrees to the base m-plane and preferably 45 degrees. For example, the cutting lines 151 to 156 shown in FIG. 6 are set along the determined cutting planes.
(g) On the rear surface 112 of the substrate 1, the lower electrode 4 is formed using photolithography or the like. Specifically, a photoresist film is applied to the entire rear surface 112, and then part of the photoresist film where the lower electrode 4 is formed is removed by photolithography or the like to expose part of the rear surface 112. Subsequently, on the photoresist film and the exposed part of the rear surface 112, a second conductor layer which serves as the lower electrode 4 in the semiconductor is formed by sputtering or the like. The second conductor layer can be for example a laminate of Ti and Au and the like. The lower electrode 4 is then formed by a lift off method using a photoresist film. The lower electrode 4 is patterned so as not to be formed in regions which are subjected to dicing or where the cutting lines are set.
(h) Next, as shown in FIG. 11, the surface of the semiconductor layer 2 where the upper electrode 3 is formed is attached to adhesive tape 200. The upper electrode 3 is not shown in FIG. 11 (not shown also in the followings).
(i) Along the set cutting lines, trenches are formed in the rear surface 112 of the substrate 1 by dicing. Specifically, as shown in FIG. 12, trenches 110 reaching middle points between the front surface 111 and the rear surface 112 from the rear surface 112. In the example shown in FIG. 12, the middle points are at distance d from the front surface 111. When the size of the rectangular chips obtained by dividing the substrate 1 is 300×300 μm, the trenches 110 are formed into a grid with a spacing of 300 μm in the rear surface 112 of the substrate 1. As described above, the trenches 110 are formed in the region where the lower electrode 4 is not formed. A dicing blade 301 used in dicing can be, for example, a dicing blade in which the edge coming into the substrate 1 has a V-shaped cross section vertical to a cutting plane as shown in FIG. 2. For example, the dicing blade 301 can be a dicing blade which has a thickness W of 60 μm and has a blade angle φ of the edge is 60 degrees. Accordingly, as shown in FIG. 12, the trenches 110 whose bottoms are V-shaped are formed in the rear surface 12 of the substrate 1.
(j) Stress is applied to the front surface 111 of the substrate 1 corresponding to the trenches 110 for cleavage of the substrate 1. Specifically, as shown in FIG. 13, a cleavage blade 302 is brought into contact with the position on the front surface 111 corresponding to the apex of the V shape formed in the bottom of each trench 110 formed in the rear surface 112 for braking, thus cleaving the substrate 1. The cleavage face is from the middle point between the front surface 111 and the rear surface 112 to the front surface 111.
(k) The adhesive tape 20 is then expanded, thus obtaining the semiconductor device shown in FIG. 1.

In the semiconductor device obtained by cutting the substrate 1 with the above method, the side surfaces of the first cuboid region 11 adjacent to the front surface 111 are cleavage planes cut by the cleavage. The side surfaces of the second cuboid region 13 adjacent to the rear surface 112 and the side surfaces of the truncated rectangular pyramid region 12 are cutting surfaces by dicing.

The blade edge of the dicing blade 301 has a V-shape. Accordingly, the bottom of each trench formed in the rear surface 112 of the substrate is V-shaped, and the yield of cleavage is increased. This is because the stress applied from the front surface 111 of the substrate 1 is not distributed but concentrated on the tip of the V-shape in the bottom of the trench.

The distance d between the apex of the V-shape formed in the bottom of each trench 110 and the front surface 111 of the substrate 1 is set so that the part between the apex of each trench 110 and the front surface 111 can be cleaved to provide even cutting faces with a good yield and so that damages due to dicing do not occur in the semiconductor layer 2. For example, the distance d is set to about 50 μm.

The V-shape of the bottoms of the trenches 110 depends on the blade angle φ at the edge of the blade. Specifically, the shape of the truncated rectangular pyramid region 12 depends on the shape of the edge of the dicing blade 301. For example, when the blade angle φ at the edge of the blade 301 is 60 degrees, the angles between the front surface 111 and the side faces of the truncated rectangular pyramid region 12 are 30 degrees.

Moreover, the width of the trenches 110 near the rear surface 112 is determined by blade thickness W of the dicing blade 301. The difference in area between the front surface 111 and the rear surface 112 depends on the blade thickness W of the dicing blade 301. Specifically, the difference in length between the sides of the front surface 111 and the rear surface 112 is equal to the blade thickness W of the diving blade 301.

The above description shows an example where the positions of the cutting planes are determined between the process of polishing the rear surface 112 and the process of forming the lower electrode 4 but may be performed before the process of patterning the lower electrode 4. For example, the positions of the cutting planes may be determined before the process of polishing the rear surface 112. When dicing of the lower electrodes 4 is performed simultaneously with dicing of the substrate 1, the positions of the cutting planes may be determined after the lower electrodes 4 is formed.

Generally, it is difficult to cut a substrate into chips by dicing in the case where the substrate has high Mohs hardness like a sapphire substrate used as a growth substrate of GaN semiconductors. To dice the sapphire substrate, it is necessary to increase the diameter of a diamond particle molded in the dicing blade with a large diameter, and it is therefore necessary to increase the blade thickness of the dicing blade. The dicing region in the surface of the substrate is increased, and the area use efficiency of the substrate is reduced, thus increasing the manufacturing cost. Furthermore, using such diamond particles of large size increases the roughness of the side surfaces of each chip.

However, the Mohs hardness of the ZnO semiconductor is 4 and is equal to that of GaAs. Accordingly, the dicing blade 301 can be a dicing blade normally used in dicing of a GaAs substrate. For example, the dicing blade 301 can be a resin or metallic blade with a plurality of diamonds provided in resin or metal or the like. The bond material of the metal blade is metal, and the bond material of the resin blade is thermosetting resin (phenol resin or the like). If such a dicing blade is used in forming the trenches in the front surface 111 of the substrate 1, the dicing plate 301 exhibits little wear and can be used in dicing for long period. It is preferable that the blade angle at the edge of the dicing blade 301 is narrower in the light of forming the trenches. However, in the light of wearing, the preferable blade angle is about 45 to 60 degrees.

In the case of performing dicing, the substrate 1 is not necessarily ground and thinned. However, in the light of wearing of the dicing blade 301, it is preferable to lap and thin the substrate 1 before dicing. Although the substrate 1 is preferable to make thinner in the light of wearing of the dicing blade 301, it is only necessary to grind the substrate 1 to a thickness of about 100 μm considering handling of the substrate 1 at the lapping.

The trenches may be formed in the rear surface 112 using a first thick dicing blade and a second dicing blade thinner than the first dicing blade without grinding the substrate 1. Specifically, using the thick first dicing blade, trenches are formed up to a proper depth, and then trenches with V-shaped bottoms are formed in the rear surface 112 using the second dicing blade with a V-shaped edge.

As described above, in the method of manufacturing a semiconductor device according to the embodiment of the present invention, the trenches with V-shaped bottoms are formed by setting the angle to the base m-plane to 40 to 50 degrees and more preferably to 45 degrees. Accordingly, each cutting plane extends between the m-plane and the a-plane, thus preventing production of the twin chips and cracks in chip surfaces. The substrate 1 is thus cleaved with a good yield. The side surfaces of the substrate 1 made into chips which are adjacent to the front surface 111 and the rear surface 112 are at angles of 40 to 50 degrees to the base m-plane, and the angles between the a-planes orthogonal to the base m-plane and the corresponding side surfaces are 40 to 50 degrees.

As previously described, the ZnO semiconductor has low chemical resistance and furthermore is more anisotropic than the other semiconductor materials in wet etching in which the etching rate is large in a −c plane and is small in a +c plane. Accordingly, the −c plane of the ZnO semiconductor cannot be immersed in etching liquid for long time. It is therefore difficult to remove damage due to dicing by wet etching.

However, according to the method of manufacturing a semiconductor device described with reference to FIGS. 11 to 13, first, the trenches are formed in the rear surface 112 of the substrate 1 so as not to reach the front surface 111. The stress is then applied to the front surface 111, and the part of the substrate 1 close to the front surface 111 is cut by cleavage. Accordingly, the semiconductor layer 2 formed on the front surface 111 is not damaged by dicing, thus eliminating the need to remove damage of chips by wet etching. The wet etching step after the chip forming step is not necessary, and the reduction in yield can be prevented.

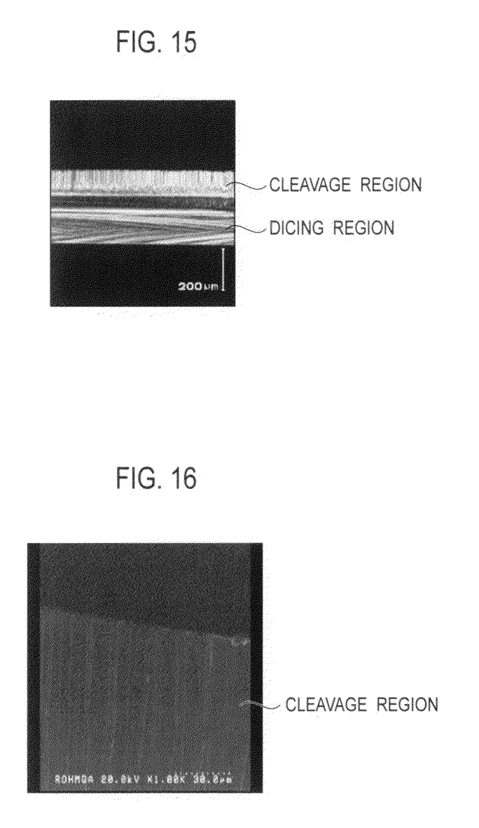

FIGS. 14 to 16 show examples of the cutting planes of the substrate 1. In FIGS. 14 to 16, the part cut by dicing is indicated as a “dicing region”, and the cleaved part is indicated as a “cleavage region”. FIG. 14 is a cross-sectional view in the case where trenches are formed in a grid manner in the rear surface 112 of the substrate 1 and then the substrate 1 is cut along cutting lines extending in the same direction. In FIG. 14, it is found that a trench with a V-shaped bottom is formed. FIG. 15 is an optical micrograph of the dicing and cleavage regions, and FIG. 16 is an enlarged micrograph of the cleavage region shown in FIG. 15. The surface roughness in the cleavage region is smaller than that in the dicing region. Normally, each cutting plane of the substrate 1 in the method of manufacturing a semiconductor device described with reference to FIGS. 11 to 13 is composed of small angular faces where the m- and a-axes alternately appear. Even when the substrate 1 is cut into rectangles such as squares and rectangles, the production of twin chips, cracks in the surface, and the like can be prevented.

Moreover, according to the method of manufacturing a semiconductor device of the embodiment of the present invention, the region of the substrate 1 close to the front surface 111 is cut by cleavage, and it is therefore unnecessary to prepare a region for dicing in the front surface 111. For example, to obtain 300 μm square rectangular chips, it is necessary to prepare a dicing region with a width of 30 μm in the case of cutting the substrate 1 from the rear surface 112 to the front surface 111 using a dicing blade with a thickness of 30 μm. This results in about 20% reduction of the region where the semiconductor layer 2 can be formed. However, according to the method of manufacturing a semiconductor device of the embodiment of the present invention, it is possible to prevent the reduction of the region in the front surface 111 where the semiconductor layer 2 can be formed and prevent the reduction in number of chips obtained, thus preventing an increase in manufacturing cost.

As described above, according to the method of manufacturing a semiconductor device of the embodiment of the present invention, it is possible to provide a method of manufacturing a semiconductor device which allows the substrate 1 to be divided into rectangular chips with the reduction in yield being prevented.

### OTHER EMBODIMENTS

In the description of the previous embodiment, the example that the base nonpolar plane used to determine cutting planes is set to an m-plane but may be set to an a-plane.

Moreover, the above description shows the example in which the semiconductor layer 2 includes a structure of the n-type MgZnO layer 21, undoped MgZnO layer 22, and p-type MgZnO layer 23 which are stacked in this order. However, the semiconductor layer 2 may have another structure such as a pn-junction in which the n-type semiconductor layer and p-type semiconductor layer are directly joined to each other. Alternatively, the semiconductor layer may include a superlattice structure in which the undoped MgZnO layer 22 is composed of a MgZnO semiconductor.

Various modifications will become possible for those skilled in the art after receiving the teachings of the present disclosure without departing from the scope thereof.

What is claimed is:

1. A semiconductor device comprising:
a substrate composed of a zinc oxide semiconductor having a hexagonal crystal structure, the substrate comprises:
a first principal surface which is a polar plane; and
four side surfaces which are adjacent to the first principal surface, the side surfaces being orthogonal to the principal surface and are at angles of 40 to 50 degrees to a base nonpolar plane orthogonal to the first principal surface; and
a semiconductor layer provided on the first principal surface.

2. The semiconductor device of claim 1, wherein the substrate comprises:
a first cuboid region including the first principal surface as a face;
a truncated rectangular pyramid region including a face of the first cuboid region opposite to the first principal surface as a base; and
a second cuboid region including a second principal surface as a face, wherein the second principal surface is smaller than the first principal surface and a face opposite to the second principal surface is a truncated surface of the truncated triangular pyramid region.

3. The semiconductor device of claim 2, wherein faces of the first cuboid region adjacent to the first principal surface are cleavage planes.

4. The semiconductor device of claim 1, wherein angles between the four side surfaces and the base nonpolar plane are 45 degrees.

5. The semiconductor device of claim 1, wherein the base nonpolar surface is an m-plane.

6. The semiconductor device of claim 1, wherein the first principal surface has a rectangular shape.

7. The semiconductor device of claim 1, wherein the substrate has a thickness of not more than 100 μm.

8. The semiconductor device of claim 1, wherein the semiconductor layer is composed of a zinc oxide semiconductor and includes a structure in which a first semiconductor layer of a first conductive type, an active layer, and a second semiconductor layer of a second conductive type are stacked in this order.

9. A method of manufacturing a semiconductor device in which a substrate is divided into a plurality of chips, the substrate including a first polar principal surface and a second principal surface opposite to the first principal surface, the method comprising:
setting a base nonpolar plane;
determining positions of cutting planes at angles of 40 to 50 degrees to the base nonpolar plane; and
cutting the substrate along the cutting planes into the plurality of chips.

10. The method of claim 9, wherein cutting the substrate comprises:
forming a trench from the second principal surface up to a middle point between the first and second principal surfaces; and
cleaving the substrate from the middle point to the first principal surface along the trench.

11. The method of claim 10, wherein the trench is formed by a dicing blade of which edge part has a V-shaped cross section vertical to the cutting planes.

12. The method of claim 11, wherein blade angle of the edge part of the dicing blade is 40 to 60 degrees.

13. The method of claim 10, wherein the trench is formed by sequentially using a first dicing blade and a second dicing blade thinner than the first dicing blade.

14. The method of claim 10, wherein stress is applied to the first principal surface for cleaving the substrate.

15. The method of claim 9, wherein the cutting planes are determined to make the first principal surface rectangular.

16. The method of claim 9, wherein an angle between each of the cutting planes and the base nonpolar plane is at 45 degrees.

17. The method of claim 9, wherein the base nonpolar plane is an m-plane.

18. The method of claim 9, further comprising:
stacking a first semiconductor layer of a first conductive type, an active layer, and a second semiconductor layer of a second conductive type on the substrate in this order, the layers being composed of a zinc oxide semiconductor.

19. A semiconductor device comprising:
a substrate which is composed of a zinc oxide semiconductor having a hexagonal crystal structure, the substrate comprises:
a first principal surface which is a polar plane; and
four side surfaces which are adjacent to the first principal surface and orthogonal to the principal surface; and
a semiconductor layer provided on the first principal surface,
wherein the four side surfaces are substantially different from nonpolar a- or m-planes and planes equivalent to the a- or m-planes.
